(19) United States
(12) Patent Application Publication
(10) Pub. No.: US 2025/0335657 A1
(43) Pub. Date: Oct. 30, 2025

(54) SYSTEMATIC DETERMINATION OF A REPRESENTATIVE SAMPLE FOR SERIAL PRODUCTS

(71) Applicant: Robert Bosch GmbH, Stuttgart (DE)

(72) Inventors: Philip Lucas Neureuther, Neckarwestheim (DE); Stefan Gruener, Auenwald (DE); Kevin Schmidt, Herrenberg (DE); Mark Philipp Riek, Abtsgmuend (DE); Nicola Henkelmann, Vaihingen/Enz (DE); Paul Milbaier, Stuttgart (DE)

(21) Appl. No.: 19/190,615

(22) Filed: Apr. 26, 2025

(30) Foreign Application Priority Data
Apr. 29, 2024 (DE) 10 2024 204 017.7

(51) Int. Cl. G06F 30/20; G06Q 10/0639

(52) U.S. Cl. CPC G06F 30/20; G06Q 10/06395

(57) ABSTRACT

A computer-implemented method for determining representative parameterized simulation models of a parameterizable analytical simulation model for a product, in particular a steer-by-wire steering system and/or a steering system for highly automated driving, is disclosed. The method includes determining a predetermined number of parameterized simulation models based on a dissimilarity metric, wherein the dissimilarity metric defines a distance between two respective parameterized simulation models, and wherein a plurality of representative parameterized simulation models results.

This application claims priority under 35 U.S.C. § 119 to patent application no. DE 10 2024 204 017.7, filed on Apr. 29, 2024 in Germany, the disclosure of which is incorporated herein by reference in its entirety.

### BACKGROUND

Serial products (in particular large-serial products) such as steering systems are subject to a scattering of the product parameters such as frictions, elasticities and/or inertia due to manufacturing tolerances and inaccuracies.

Furthermore, serial products are subject to additional parameter scattering due to aging, e.g., due to wear and/or environmental factors. All real world value ranges and combinations of the parameter scattering of a serial product form its so-called “operational design domain” (ODD).

Typically, a simulation model (or model for short) of a product only incorporates its essential or relevant properties, which leads to simplification-related deviations between real and modeled behavior. The parameter scattering in the ODD results in an additional deviation for each individual serial product between its real behavior and the associated simulation model, which is often focused on the representation of a product with nominal parameters. This simulation model, including the simplification and scatter-related model deviations or uncertainties throughout the ODD, is often the basis for developing a product regulation and/or for a simulation-based product release. Since a full characterization of the model uncertainties of a serial product is generally too complex, the simulation models are compared with a few real product samples (also referred to simply as samples).

Typically, the product samples are selected as follows:
Samples with minimum, maximum and/or nominal product parameters which are the most important, e.g., according to expert opinion.
Samples with product parameters defined by experts.

Therefore, it is not guaranteed that the selected product samples adequately represent the entire ODD and thereby allow for characterization of the model uncertainties in the ODD due to simplification and scattering.

One potential problem to be solved that underlies the disclosure, for example, is to provide a method in which sufficiently representative product samples may be selected for a serial product. Another potential problem to be solved, for example, is enabling characterization of the model uncertainties in the ODD due to simplification and scattering.

Compared to traditional steering systems, steer-by-wire (SbW) steering systems and/or steering systems for highly automated driving (HAD) are subject to stricter standardized requirements for product approval. In order to ensure that the real testing and trials required as a result of the stricter release requirements for SbW and HAD steering systems produced in (larger) series do not increase exceptionally sharply compared to traditional steering systems, the industry is focusing on simulation-based approval processes. For such simulation-based approval, a validated and/or verified simulation model of the steering system with known model uncertainties is essential.

In principle, a variety of different methods are known for validating and/or verifying various aspects of a simulation model or the entire model. However, there is currently no method by which a systematic or complete characterization of the simplification and scattering-related model uncertainties in the ODD of a (large) serial product is possible. In particular, there is no method for the systematic or optimal selection of, for instance, a few product samples that are representative of the entire ODD with a quantifiable residual uncertainty and thereby allow a systematic characterization of the model uncertainties in the ODD.

Furthermore, steering systems are subject to a non-negligible parameter scattering and are mostly operated in a closed control loop. This is why robust governors are often designed for steering systems by methods established in control technology. However, these design procedures require a model with known uncertainties for the product. There is currently no method for establishing one or more models with known uncertainties that also have a known representative range in the ODD and are together representative of the entire ODD.

Thus, a further problem to be solved, which is the basis of the disclosure, also lies in the context of establishing one or more models with known uncertainties for a controller design, which also have a known representative range in the ODD and are together representative of the entire ODD.

Various metrics are known in the system theory that quantify and thus compare the dissimilarity of two systems-systems and products may be considered equivalent in the following. The following section explains the gap metric, v-gap metric, and L2 metric.

The gap metric quantifies the dissimilarity of the unregulated (open-loop) input/output behavior of two systems P1 and P2 in terms of their stability and performance properties in controlled operation (closed-loop) with a scalar in the real interval [0, 1]. A near 0 metric result means that both systems are very similar and each P1-stabilizing controller also stabilizes the P2 system with a similar controlled performance. A metric result of 0 means that the systems P1 and P2 under consideration behave exactly identically. On the other hand, a metric result close to or at 1 indicates that the systems P1 and P2 are very dissimilar. Furthermore, statements on the robust stability of closed control loops with model uncertainties are possible with the gap metric. An explicit controller design is necessary for the evaluation of the gap metric. Details on the definition and characteristics of the gap metric are described in chapter 17 of the book “Essentials of Robust Control”, Kemin Zhou and John C. Doyle, 1st edition, Pearson, 1997, ISBN: 9780135258332.

The system theoretical statements and implications of the v-gap metric are very similar to the gap metric, however, both metrics have a different basic design. A controller design is not necessary for the evaluation of the v-gap metric, but rather a number of turns study necessary for the systems P1 and P2 to be compared. Details on the definition and characteristics of the v-gap metric are set forth in chapter 17 of the book “Essentials of Robust Control”, Kemin Zhou and John C. Doyle, 1st edition, Pearson, 1997, ISBN: 9780135258332 or in the publication “Frequency domain uncertainty and the graph topology”, Glenn Vinnicombe, IEEE Transactions on Automatic Control, vol. 38, no. 9, September 1371-1383 September 1993, DOI: 10.1109/9.237648.

The definition of the L2 metric corresponds to the v-gap metric without a number of turns study. For this reason, the principle statements and implications of both metrics are similar, but the L2 metric has less theoretical validity. Details on the definition and characteristics of the L2 metric are described in chapter 17 of the book “Essentials of Robust Control”, Kemin Zhou and John C. Doyle, 1st edition, Pearson, 1997, ISBN: 9780135258332.

All three aforementioned dissimilarity metrics are known to have the following characteristics:

The metrics quantify the dissimilarity of two systems in terms of stability and performance characteristics in controlled operation based on the unregulated input/output behavior.
Using the metric results, it can be decided whether two systems P1 and P2 are sufficiently similar so that P1 can be considered representative of P2.
The metric results may also be interpreted as (system-theoretical) distances between the compared systems.
For all systems to be compared, the following applies: L2 result≤v-gap result≤gap result.

### SUMMARY

A first general aspect of the present disclosure relates to a computer-implemented method for determining representative parameterized simulation models of a parameterizable analytical simulation model to a product, in particular a steer-by-wire steering system and/or a steering system for highly automated driving.

The method comprises determining a predetermined number of parameterized simulation models based on a dissimilarity metric, wherein the dissimilarity metric defines a distance between two respective parameterized simulation models, wherein a plurality of representative parameterized simulation models results.

A second general aspect of the present disclosure relates to a computer system adapted to perform the computer-implemented method of determining representative parameterized simulation models of a parameterizable analytical simulation model to a product according to the first general aspect (or an embodiment thereof).

A third general aspect of the present disclosure relates to a computer program adapted to perform the computer-implemented method of determining representative parameterized simulation models of a parameterizable analytical simulation model to a product according to the first general aspect (or an embodiment thereof).

A fourth general aspect of the present disclosure relates to a computer-readable medium or signal that stores and/or contains the computer program according to the third general aspect (or an embodiment thereof).

By the method proposed herein according to the first general aspect (or embodiment thereof), a few product samples may be systematically selected based on a model-based criterion to represent the entire ODD of a serial product with a quantifiable residual uncertainty.

In particular, the following advantages can be achieved as compared to the prior art by the method proposed herein according to the first general aspect (or one embodiment thereof):
Systematic approach to selecting product samples representative of the entire ODD;
Quantifiable residual uncertainty of the product samples with respect to the entire ODD;
Systematic characterization of the simplification and scattering-related model uncertainties throughout the ODD;
Predictable representative ranges of the respective product samples throughout the ODD;
Systematically derivable requirements for the manufacturing accuracy of the product samples;
Systematically derivable requirements for the design of a robust product regulation; and/or
Optional search for product parameters or combinations that change product behavior to a particular significant extent.

The method proposed herein according to the first general aspect (or embodiment thereof) may be used in the development of real products—e.g., steer-by-wire (SbW) steering systems—in the design phase and/or in the system development (i.e., after the design phase).

In the design phase, for example, the method can be used to systematically select (e.g., a few) product samples that are representative of all the ranges and combinations of values that occur in reality in the parameter scattering of a serial product (i.e., for the entire ODD). Moreover, by way of intermediate results of the method, individual product parameters or combinations can be found that have a particularly strong impact on the product behavior.

Based on the representative product samples, in the further system development the uncertainties caused by parameter scattering and simplifications in modeling can be systematically characterized between the real product behavior and its modeled behavior throughout the ODD. The simulation model, including the characterized model uncertainties, can then be used to develop a product regulation and/or for simulation-based product release.

In addition, for example, in the system development using the method proposed here, any number of controller design models (i.e., one or more representative models for a controller design) can be systematically prepared, including the associated model uncertainties, which each have a known representative range in the ODD and which are together representative of the entire ODD. For example, these controller design models may be used to systematically develop a gain scheduling control for the product, taking into account the known model uncertainties and representative ranges.

The method proposed herein according to the first general aspect (or embodiment thereof) may be applicable in particular as part of a simulation-based release process for SbW and HAD steering systems. Here, the selection of product samples representative for the entire ODD is required for the validation and/or verification of simulation models for steering systems, for example. In principle, the method proposed herein may also be used in other (large) serial products for model validation and/or verification and/or in the course of a simulation-based release.

The method proposed herein according to the first general aspect (or any embodiment thereof) may be performed in whole or in part analytically. This can avoid costly numerical minimization of distances. In embodiments, the representative parameterized simulation models of the parameterizable simulation model may be determined accurately.

### BRIEF DESCRIPTION OF THE DRAWINGS

FIG. 1 schematically illustrates exemplary embodiments of a computer-implemented method for determining representative parameterized simulation models of a parameterizable analytical simulation model for a product, in particular a steer-by-wire steering system and/or a steering system for highly automated driving.

FIG. 2 illustrates an exemplary embodiment of the computer-implemented method.

FIG. 3a illustrates the exemplary ODD of FIG. 3b, wherein the three determined representative parameterized simulation models are representative of one exemplary and any plurality of parameterized simulation models in the ODD.

FIG. 3b illustrates an exemplary ODD with three determined representative parameterized simulation models.

### DETAILED DESCRIPTION

The method 100 proposed in this disclosure may be designed such that it can be used to select sufficiently representative product samples for a serial product. Alternatively or additionally, the method 100 may also be designed to enable characterization of the simplification and scattering-related model uncertainties in the ODD. Alternatively or additionally, the method 100 can also be designed for establishing one or more models with known uncertainties for a controller design, which also have a known representative range in the ODD and are together representative of the entire ODD.

The systematic and model-based selection of representative product samples is described below.

The method 100 may first be designed to determine representative parameterized simulation models of a parameterizable analytical simulation model. Alternatively or additionally, the method 100 may be designed to determine representative parameter samples in the ODD. Alternatively or additionally, the method 100 may be designed for the selection of representative product samples.

The selection of representative product samples may be based on the determined representative parameterized simulation models of the parameterizable analytical simulation model and/or on the representative parameter samples in the ODD.

The method 100 is fully or partially analytical and requires that the parameterizable simulation model be in analytical form.

Firstly, a computer-implemented method 100 for determining representative parameterized simulation models of a parameterizable analytical simulation model for a product is disclosed. The product can in particular be a serial product, i.e., a product which is produced in series. The method 100—although it can also be used for a non-serial product or a small series—is particularly useful if a variety of similar products are to be produced, which may nevertheless be different (e.g., due to their production and/or material). For example, the plurality of like products may comprise >1e5 products per year, >5e5 products per year, or >1e6 products per year.

For example, the product may be a steer-by-wire steering system. Alternatively or additionally, the product may be a steering system for automated, in particular highly automated driving.

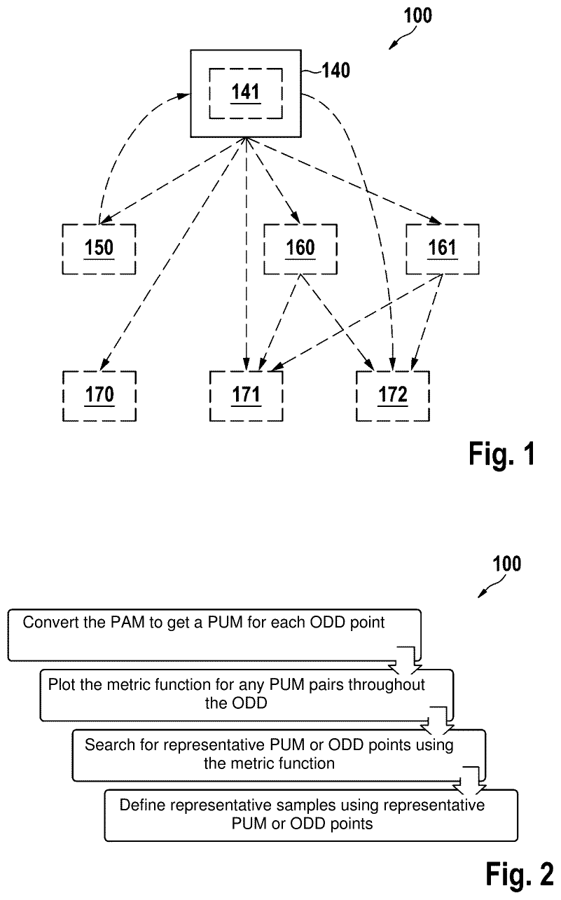

For example, as is schematically illustrated in FIG. 1 method 100 includes determining 140 a predetermined number of parameterized simulation models based on a dissimilarity metric, wherein the dissimilarity metric defines a distance between two respective parameterized simulation models, wherein a plurality of representative parameterized simulation models results.

The dissimilarity metric may be based on a gap metric, a v-gap metric, and/or an L2 metric. In particular, the dissimilarity metric may be the gap metric, the v-gap metric, or the L2 metric. Alternatively, the dissimilarity metric may be based on a combination of the gap metric, the v-gap metric, and/or the L2 metric. The dissimilarity metric may output a quantitative measure of the dissimilarity of a pair of parameterized simulation models, i.e., a quantitative measure of how similar or dissimilar the two parameterized simulation models of the pair are. In this respect, the dissimilarity metric could also be referred to as a similarity or comparison metric. The quantitative measure output by the dissimilarity metric may be referred to as distance. If the two parameterized simulation models of a pair are similar, the distance may be small. In particular, if the two parameterized simulation models of a pair are identical (i.e., maximally similar), the distance may be zero. If, on the other hand, the two parameterized simulation models of a pair are not similar, the distance may be high.

The respective two parameterized simulation models may be defined by evaluating the parameterizable analytical simulation model based on two parameter samples in an Operational Design Domain (ODD) for the product. The ODD may be defined by a numerical and/or analytical description.

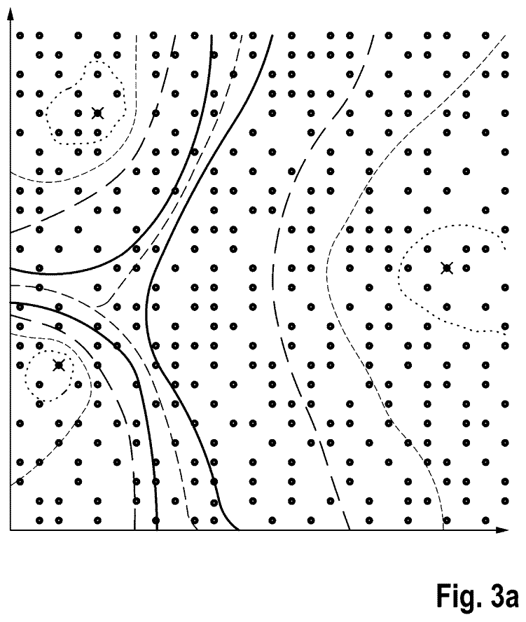

The method 100 or step 140 may further comprise converting the parameterizable analytical simulation model to obtain an associated parameterized simulation model for any ODD sample. Such a step is referred to in the exemplary embodiment in FIG. 2 as “Convert the PAM to get a PUM for each ODD point”, wherein PAM denotes the parameterizable analytical simulation model, PUM a parameterized simulation model of the parameterizable analytical simulation model, and ODD point a parameter sample in the ODD.

The method 100 or step 140 may further comprise setting up a dissimilarity metric function for any pair of parameterized simulation models throughout the ODD. Such a function may be a chaining of the dissimilarity metric to two converted parameterizable analytical simulation models. Such a step is referred to in the exemplary embodiment of FIG. 2 as “Plot the metric function for any PUM pairs throughout the ODD”, wherein the metric function also refers to the dissimilarity metric function.

The actual determination 140 of the predetermined number of parameterized simulation models based on the dissimilarity metric is referred to in the exemplary embodiment of FIG. 2 as “Search for representative PUM and ODD points by metric function,” wherein the representative PUM refers to the plurality of representative parameterized simulation models and the ODD points in turn denotes the ODD samples.

The plurality of representative parameterized simulation models may be defined such that the distances between each parameterized simulation model (in the ODD) and the respective representative parameterized simulation model nearest it (in view of the dissimilarity metric) are minimal (likewise in the ODD). For example, these distances may be minimal in a predetermined finite-dimensional norm. It is also contemplated, for example, that the distances be modified, in particular weighted, prior to application of the finite-dimensional norm, e.g., based on pre-existing knowledge about the product and/or its ODD at the time of execution of the method 100.

In this case, the minimum distances, in particular the minimum distance in the finite-dimensional norm can be determined. Minimization can be carried out in a mathematically strict sense or in an approximate sense. For example, it may be sufficient to find a local minimum instead of a global minimum. Thus, the determination 140 of the predetermined number of representative parameterized simulation models may be made accurately or approximately based on the dissimilarity metric.

For example, the predetermined finite-dimensional norm may be a p-norm for any p in the interval [1, +Inf], wherein +Inf positively denotes Infinite. In particular, the p-norm may be, for example, a sum norm (i.e., p=1). Here, therefore, the sum of all distances can be minimal. In another example, the p-norm may be a Euclidean norm (i.e., p=2). Here, the Euclidean distance can be minimal. In yet another example, the p-norm may be a maximum norm (p=Inf). In the case of the maximum norm, the plurality of representative parameterized simulation models may thus be defined such that the maximum of all distances of each parameterized simulation model to its respective nearest representative parameterized simulation model is minimal.

The determination 140 of the predetermined number of parameterized simulation models (leading to the plurality of representative parameterized simulation models) may be based on an analytical optimization. Alternatively or additionally, the determination 140 of the predetermined number of parameterized simulation models may be based on an approximate optimization. Alternatively or additionally, the determination 140 of the predetermined number of parameterized simulation models may be based on a numerical optimization. In particular, the determination 140 of the predetermined number of parameterized simulation models may be based on a combination of an analytical optimization, an approximate optimization, and/or a numerical optimization. The analytical, approximate, and/or numerical optimization may be performed on the ODD (i.e., on the entire ODD). For example, this means that when determining 140 the predetermined number of parameterized simulation models, each parameter sample in the ODD is considered a possible representative parameter sample (or its associated representative parameterized simulation model). It may also mean that any combination of parameter samples in the ODD are contemplated as possible representative parameter samples (or as their associated representative parameterized simulation models). It may also further mean that the parameter samples associated with the two parameterized simulation models in total comprise all of the pairs of parameter samples in the ODD.

Alternatively, the determination 140 of the predetermined number of the parameterized simulation models may only be related to a part of the ODD (e.g., in the case of certain questions or to further investigate the ODD).

For example, as illustrated schematically and as an option in FIG. 1 method 100 may further comprise determining 141 a measure of the representation of the representative parameterized simulation models based on the predetermined number and/or minimum distances, particularly the minimum distance in the finite-dimensional norm. For example, the measure of representation may comprise a quantifiable residual uncertainty of the product samples with respect to the ODD.

As also illustrated schematically and as an option, for example, in FIG. 1 the method 100 may further comprise adjusting 150, in particular increasing the predetermined number if the measure of representation fails to satisfy a predetermined criterion. For example, the predetermined criterion may be satisfied when the measure of representation is sufficiently large. After adjusting 150, in particular increasing the pre-determined number, the method 100 can be repeated, e.g., until the measure of representation satisfies the predetermined criterion (i.e., e.g., until the measure of representation is sufficiently large).

For example, as illustrated schematically and as an option in FIG. 1 the method 100 may further comprise determining 160 the respective parameter samples associated with the representative parameterized simulation models as the representative parameter samples of the parameterizable analytical simulation model.

As also illustrated schematically and as an option, for example in FIG. 1 the method 100 may further comprise determining 161 product samples associated with the representative parameterized simulation models, wherein a plurality of representative product samples results. The determination 161 of the product samples associated with the representative parameterized simulation models may in particular be based on the representative parameter samples of the parameterizable analytical simulation model. For example, the determination 161 of the plurality of representative product patterns may be carried out by matching a database of stored parameter samples of real product patterns, particularly based on a similarity ratio. In the event of unsatisfactory similarity, one or more instructions may be issued as to how a sufficiently satisfactory representative product sample may be produced from a real product sample (e.g., by setup, shimming, etc.).

Steps 160 and 161, in the exemplary embodiment of FIG. 2 are referred to as “Define representative samples using representative PUM or ODD points”. Here, the representative PUM, in turn, refers to the plurality of representative parameterized simulation models and the ODD points refer to the ODD samples.

For example, as illustrated schematically and as an option in FIG. 1 the process 100 may further comprise configuring 170 a control of the product based on at least one representative parameterized simulation model. The design 170 of the control of the product may be based in particular on the plurality of representative parameterized simulation models. This enables the drafting and/or design of a robust control of the product. In particular, the control of the product may be designed particularly robustly and reliably. In particular, this may increase the safety of the product.

As also illustrated schematically and as an option, for example, in FIG. 1 the method 100 may further comprise testing 171 of one or more requirements for the product based on at least one representative parameterized simulation model. Testing 171 of the one or more requirements for the product can be based in particular on the plurality of the representative parameterized simulation models. The product can thus be designed robustly and reliably. In particular, this can also increase the safety of the product.

For example, as illustrated schematically and as an option in FIG. 1 the process 100 may further include identifying 172 one or more of the representative parameterized simulation models and/or the representative parameter samples that have a greater impact on the product and/or its behavior (e.g., steering behavior). This may be done, for example, by a sensitivity analysis. This can improve understanding of the product and its behavior. In particular, in the case of higher dimensional ODDs, this may be useful because the ODD may no longer be directly inspected.

FIG. 2 shows an exemplary embodiment of the method 100. For example, the following steps may be performed here in sequence:
“Convert the PAM to get a PUM for each ODD point”
“Plot the metric function for any PUM pairs throughout the ODD”
“Search for representative PUM and ODD points by metric function”
“Define representative samples using representative PUM or ODD points”

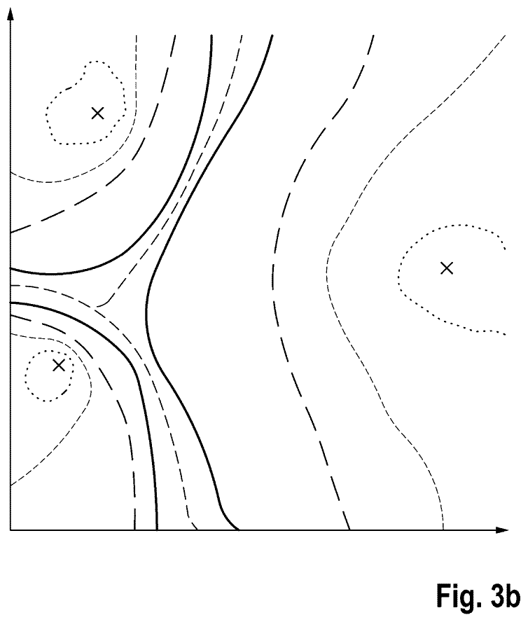

FIG. 3a illustrates the exemplary ODD of FIG. 3b, wherein the three determined representative parameterized simulation models are representative of one exemplary and any plurality of parameterized simulation models in the ODD.

FIG. 3b illustrates an exemplary ODD with three determined representative parameterized simulation models (more precisely, their associated parameter samples). These are each represented by a cross in the ODD. Here, three simulated models or their parameter samples in the ODD were thus determined to be representative, 140, 160, namely such that the distances (according to the dissimilarity metric) of each simulated model to the nearest respective representative simulation model are minimal. Some of these parameterized simulation models or their associated parameter samples are shown in FIG. 3a, respectively, as a completed point in the ODD for illustrative purposes only.

In this example, the ODD is a two-dimensional product space, i.e., it is subtended by two parameters (one parameter in the x direction, another parameter in the y direction), which can each take on values within an interval. In general, the ODD need not be a product space, but can be a (any) variety. The dimension of the ODD may be arbitrary.

For this example, in 3D, i.e., in the z-direction orthogonal to the sheet plane, the distance (according to the dissimilarity metric) of each point in the ODD (i.e., specifically its parameterized simulation model) to the nearest representative parameterized simulation model could be represented. In 2D, instead, some isolines are represented in the z-direction with respect to this variable. For example, the three solid lines form an isoline, i.e., they have the same z-value. In addition, three further isolines are shown—extending approximately around the crosses. In addition to the isolines, a boundary of spheres of influence (dashed lines intersecting in a point) of the respective representative parameterized simulation models is drawn.

A computer system adapted to perform the computer-implemented method 100 for determining representative parameterized simulation models of a parameterizable analytical simulation model for a product is further disclosed. The computer system can comprise a processor and/or a working memory.

A computer program is further disclosed that is adapted to perform the computer-implemented method 100 for determining representative parameterized simulation models of a parameterizable analytical simulation model for a product. The computer program may, for example, be present in interpretable or compiled form. For execution, it may be loaded (also in portions) into the RAM of a computer, for example, as a bit or byte sequence.

Furthermore disclosed is a computer-readable medium or signal, which stores and/or contains the computer program. The medium may, for example, comprise one of RAM, ROM, EPROM, HDD, SDD, . . . on/in which the signal is stored.

What is claimed is:

1. A computer-implemented method for determining representative parameterized simulation models of a parameterizable analytical simulation model for a product, comprising:
determining a predetermined number of parameterized simulation models based on a dissimilarity metric, wherein the dissimilarity metric defines a distance between two respective parameterized simulation models, and wherein a plurality of representative parameterized simulation models results.

2. The method of claim 1, wherein the dissimilarity metric is based on a gap metric, a v-gap metric, and/or an L2 metric.

3. The method of claim 1, wherein the plurality of representative parameterized simulation models is defined such that the distances of each parameterized simulation model to the nearest respective representative parameterized simulation model are minimal.

4. The method of claim 1, wherein the predetermined finite-dimensional norm is a p-norm for p in [1, +Inf], a Euclidean norm, or a maximum norm.

5. The method according to claim 3, further comprising:
determining a measure for the representation of the representative parameterized simulation models based on the predetermined number and/or the minimum distance in the finite-dimensional norm.

6. The method of claim 1, wherein the respective two parameterized simulation models are defined by evaluating the parameterizable analytical simulation model based on two parameter samples in an operational design domain (ODD) for the product.

7. The method of claim 1, wherein the determination of the predetermined number of parameterized simulation models is based on an analytical, approximate, and/or numerical optimization.

8. The method of claim 6, wherein:
the determination of the predetermined number of parameterized simulation models is based on an analytical, approximate, and/or numerical optimization, and
the analytical, approximate, and/or numerical optimization is performed on the ODD.

9. The method according to claim 1, further comprising:
determining the respective parameter samples associated with the representative parameterized simulation models as the representative parameter samples of the parameterizable analytical simulation model.

10. The method according to claim 1, further comprising:
determining product samples associated with the representative parameterized simulation models, wherein a plurality of representative product samples results based on the representative parameter samples of the parameterizable analytical simulation model.

11. The method according to claim 1, further comprising:
configuring a controller of the product based on at least one representative parameterized simulation model; and/or
testing one or more requirements for the product based on the at least one representative parameterized simulation model.

12. The method according to claim 1, further comprising:
identifying one or more of the representative parameterized simulation models and/or the representative parameter samples that have a greater impact on the product.

13. A computer system configured to perform the computer-implemented method for determining representative parameterized simulation models of a parameterizable analytical simulation model for a product according to claim 1.

14. A computer program configured to perform the computer-implemented method for determining representative parameterized simulation models of a parameterizable analytical simulation model for a product according to claim 1.

15. A computer-readable medium or signal that stores and/or contains the computer program of claim 14.

16. The method of claim 1, wherein the product is a steer-by-wire steering system and/or a steering system for highly automated driving.

17. The method of claim 3, wherein the plurality of representative parameterized simulation models is defined such that the distances of each parameterized simulation model to the nearest respective representative parameterized simulation model are in a predetermined finite-dimensional norm.

18. The method of claim 1, wherein the predetermined finite-dimensional norm is a sum norm, a Euclidean norm, or a maximum norm.

19. The method according to claim 5, further comprising:
increasing the predetermined number if the level of representation does not sufficiently satisfy a predetermined criterion.

20. The method according to claim 1, further comprising:
configuring a controller of the product based on the plurality of representative parameterized simulation models; and/or
testing one or more requirements for the product based on the plurality of representative parameterized simulation models.
